(19) United States
(12) Patent Application Publication
(10) Pub. No.: US 2008/0170502 A1
(43) Pub. Date: Jul. 17, 2008

(54) Method and system for monitoring data flow in an IP network device

(76) Inventors: Thomas Benton, Naperville, IL (US); Janusz Biegaj, Hinsdale, IL (US)

Correspondence Address: ARRIS INTERNATIONAL, INC, 3871 LAKEFIELD DRIVE, SUWANEE, GA, 30024, US

(21) Appl. No.: 11/756,590

(22) Filed: May 31, 2007

Related U.S. Application Data
(60) Provisional application No. 60/809,468, filed on May 31, 2006.

(51) Int. Cl. G01R 31/08

(52) U.S. Cl. 370/235

(57) ABSTRACT

User input values define an inspection window for evaluating a desired traffic element portions of a bitstream. Offset and reference values determine the start of the window with respect to the bitstream and values for a filter register and mask registers define the size of the window. As the bitstream ‘passes through’ the window, the bits in the window are compared to bits in the filter and mask registers. Traffic element portions that match the criteria of the window are stored into a storage device formed with a FPGA. Filter controls that are also formed with, the FPGA determine that the window criteria are met; and send a control signal to a capture apparatus gate to permit the current bitstream portion into a storage device that is also formed with the FPGA. The stored element portions are later evaluated by the CMTS and/or operation personnel.

### CROSS REFERENCE TO RELATED APPLICATION

This application claims the benefit of priority under 35 U.S.C. 119(e) to the filing date of Benton, et. al., U.S. provisional patent application No. 60/809,468 entitled “A method and apparatus for monitoring data flow in an IP network device,” which was filed May 31, 2006, and is incorporated herein by reference in its entirety.

### FIELD OF THE INVENTION

This invention relates, generally, to communication networks and, more particularly, to evaluating traffic elements traversing a communication network.

### BACKGROUND

Currently, broadband networks may be used to provide data services arid traditional telephony service over community antenna television (“CATV”) or other communications networks using coaxial cable (“coax”) or optical fiber cable. For example, ARRIS Group, Inc. offers telephony over cable products known as VOICE PORT® and TOUCHSTONE® cable modems which interface a media terminal adaptor (“MTA”), or an embedded media terminal adaptor (“EMTA”), with a data network. In conjunction with a cable modem termination system (“CMTS”), these products are used by the CATV system operators to provide telephony and data services, typically as internet protocol traffic (“IP”). As known in the art, IP traffic is typically made up of traffic elements known as packets.

In any IP network device that processes IP traffic, observation/inspection/analysis of individual traffic elements poses a problem. Firstly, there is typically a large volume of traffic elements to inspect for a given traffic flow, or bit stream. Secondly is the problem of where the inspection and analysis takes place. Inside a network device, traffic elements are quickly disassembled and processed separately, often in parallel. Thirdly, the question of which at which layer the observation is to take place should be resolved. Typically the choices for the layer where the inspection, should take place is between Layer 2 and layer 3. In addition, the determination should be made whether the inspection, and analysis always takes place at the same time. Furthermore, data communication protocols are often bidirectional exchanges of traffic elements. For example, a TCP connection establishment requires the 3-way handshake of SYN SYN-ACK, and ACK. It is difficult to observe and evaluate all three of these messages at the same level.

It will be appreciated that for reference purposes herein, the phrase ‘network device’ will be used to mean either a Layer 2 switch or a Layer 3 router. The phrase ‘traffic element’ will be used to mean an IP Protocol Data Unit such as a packet or an Ethernet frame.

With respect to the three primary problematic issues related to evaluating traffic elements discussed above, some of the solutions proposed in the art contain limitations. For example, when traffic is external to a network device and is present on the transmission media between network components, it is possible that a tap into the media be made and a specialized device used to observe the individual traffic elements. These instruments are dedicated and expensive tools like Network Protocol Analyzers, DOCSIS Sniffers, Ethernet Packet Sniffers, etc, depending on the type of network. Through these devices individual traffic elements may be captured and analyzed.

However, tapping into transmission media by physically tapping into a medium to provide interconnection to diagnostic equipment is problematic. Using taps is typically impractical, in real IP networks as the traffic path cannot be broken without traffic disruption. Bidirectional monitoring is even more difficult because RF power levels differ in each direction and test instruments have a finite dynamic range.

When traffic is internal to a network device, visibility into traffic elements is even more problematic. Some network devices provide some visibility into internal traffic elements using a debug command. But this visibility is limited, inflexible and cannot be performed without imposing a performance penalty on the network device. Furthermore, only a limited period of traffic can be monitored and there are crude controls over the type of data captured and how it is interpreted. Debug commands typically do not provide a way to flexibly observe, capture and display the raw traffic elements.

Therefore, there is a need in the art for a method and system for peering into the traffic elements inside a network that does not have the limitations of previous solution attempts. The needed method and system should include a means for observing all traffic elements. Second, inspecting the traffic should not impose a performance penalty on the device as it performs its task. Thirdly, the solution should provide variability over what information is captured and how it is analyzed and displayed.

### BRIEF DESCRIPTION OF DRAWINGS

FIG. 1 illustrates architecture for facilitating evaluation of traffic elements.

FIG 2 illustrates detail of a trigger block.

### DETAILED DESCRIPTION

As a preliminary matter, it will be readily understood by those persons skilled in the art that the present invention is susceptible of broad utility and application. Many methods, embodiments and adaptations of the present invention other than those herein described, as well as many variations, modifications, and equivalent arrangements, will be apparent from or reasonably suggested by the present invention and the following description thereof, without departing from the substance or scope of the present invention.

Accordingly, while the present invention has been described herein in detail in relation to preferred embodiments, it is to be understood that this disclosure is only illustrative and exemplary of the present invention and is made merely for the purposes of providing a full and enabling disclosure of the invention. The following disclosure is not intended nor is to be construed to limit the present invention or otherwise to exclude any such other embodiments, adaptations, variations, modifications and equivalent arrangements, the present invention being limited only by the claims appended hereto and the equivalents thereof.

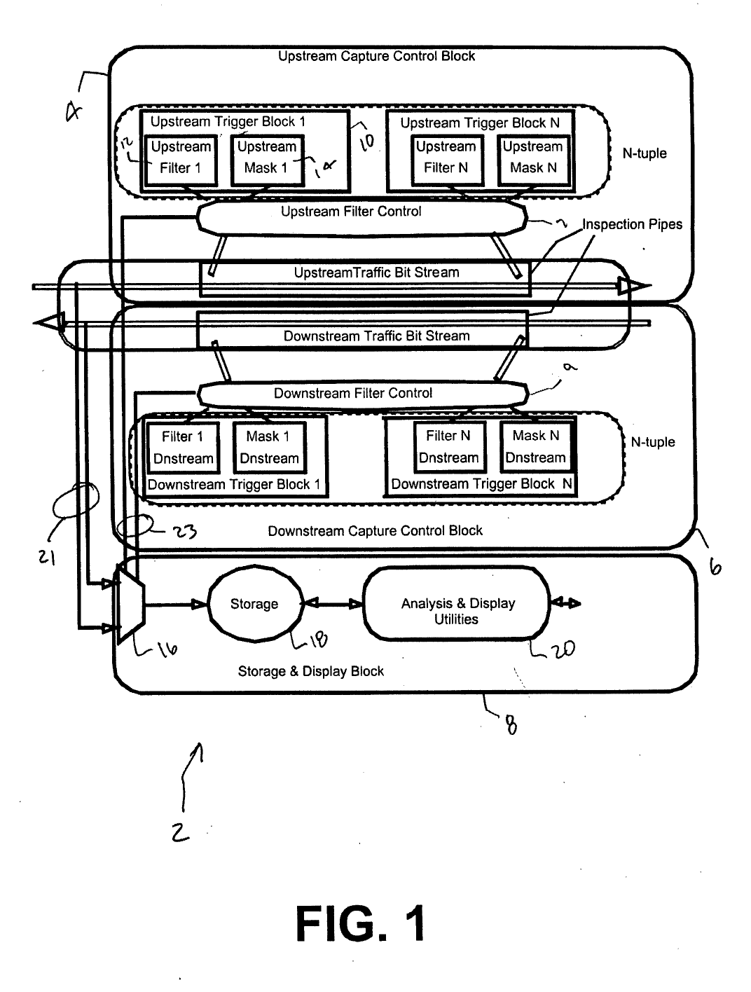

Turning now to the FIGS, FIG. 1 illustrates a system 2 for facilitating evaluation of traffic elements. System 2 includes hardware elements that are operated under software control. The primary hardware elements of system 2 include upstream capture control block 4, downstream capture control block 6 and storage and display block 8. TCP/IP devices are bidirectional, so there are typically separate upstream and downstream capture control blocks. Components of system 2 are typically implemented using Field Programmable Gate Array (“FPGA”) technology. Software control, represented by filter control blocks 7 and 9, are typically stored in RAM device that is coupled with the CMTS at an operator's head end location. The RAM devices are coupled to a CMTS processor, or processors, which execute(s) the control software in RAM.

Each upstream and downstream capture control block, referenced by numerals 4 and 6 respectively, includes an n-tuple of trigger blocks. For purposes of illustration and discussion, first upstream trigger block 10 is described in detail. First upstream filter block 10 includes a filter register 12, mask register 14, reference register and offset register (both not shown in the figure). Storage and display block 8 includes packet capture apparatus 16, storage apparatus 18 for storing software method 20 for analyzing and displaying captured packets. Capture apparatus 16 may include a mulitplexor, or a gate that opens on command, In the described aspect, inputs 23 to capture apparatus 16 carry the traffic element bit streams. The control signals are the vertical lines 23 coming from the filter controls 7 and 9, When a filter control identifies a match, it sends a Capture signal to capture apparatus 16 which opens its gate and allows the packet or other traffic element, to flow into the storage element 18.

Thus, storage 18 may be used to store copies of traffic elements being evaluated. The primary software elements that include control software and display software, are, as discussed above, typically stored in RAM, or other storage or memory devices at a CMTS that using the described aspects to evaluate traffic elements.

A user defines the number of trigger blocks to be used by defining values through a user command set. Using the user-defined values, the commands populate values for each of the trigger block elements: (e.g., reference, offset, filter, mask). These values define a sliding ‘inspection pipe’ window which transparently compares its filter values with the values found at the defined location in the bit stream. Inspection pipe is a term used to describe a virtual common pathway through which traffic elements pass. The inspection pipe's window—relative to the start of a packet's bit stream—is a function of the previously entered values (e.g., reference, offset, mask).

A reference value typically defines delineation points within a frame such as the start of L2 and L3 headers. An offset value defines the number of bytes from this reference value where the ‘inspection pipe’ window begins. The mask value defines filter bit values that are to be used to compare with the corresponding bits (relative to the offset and reference) of the traffic element being evaluated. The mask can be used to construct any bit sequence of size m and contains don't care values so that matching bit sequences do not need to be contiguous. As a data bit stream, flows through the inspection pipe unimpeded, transparent comparisons between the filter and mask values are made. If there is a match, the packet under inspection is copied into storage 18 for later analysis through the analysis and display utilities.

Simple packet inspections may require only a single trigger block, whereas more complex inspections may require multiple trigger blocks. The N filter blocks (corresponding to filter block 12 in upstream trigger block 10, but are similar for other upstream, as well as the downstream, filter blocks of other trigger blocks) may be operated independently (logical OR mode) or in a dependant (logical AND) mode. The Filter Control element incorporates the logic to implement the user-defined logic sequence. In the simpler OR mode, each filter independently compares its filter with the bit stream pattern at the specified location in the frame. Each frame containing a match is then copied into storage for later analysis. An example of this simpler mode might be to capture all packets whose DMAC matches the value specified in trigger block 10 OR packets having protocol type that matches a value specified in second upstream trigger block (not shown in the FIGS.). Another simple example might be to capture all ICMP packets.

In the more complex, mode, the Filter Control element is used to construct a user-defined logical combination of the trigger blocks and perform packet comparisons with the resulting pattern. An example of this mode might be as follows: capture a packet if its Destination MAC address (“DMAC”) matches the value defined in trigger block 1 AND the packet is a DHCP Discover AND the packets' SIP does NOT match the value defined in trigger block 3. TCP/IP devices are bidirectional, so there are separate upstream and downstream capture control blocks, reference items 6 and 8, respectively, in FIG. 1. These capture control blocks operate independently of each other.

Turning now to FIG, 2, the figure illustrates some elements of a trigger block 10, As noted above in the description of FIG. 1, upstream trigger block 10 is used for purposes of discussion, and is representative of second upstream trigger block through nth upstream trigger block, as well as downstream trigger blocks 1 . . . n. Trigger block 10 includes hardware elements containing values that are populated under software control. Trigger block 10 is typically populated with the following values: filter value, mask value, reference value and offset value. Each trigger block forms a sliding virtual inspection pipe window that may be positioned transparently anywhere over the data stream.

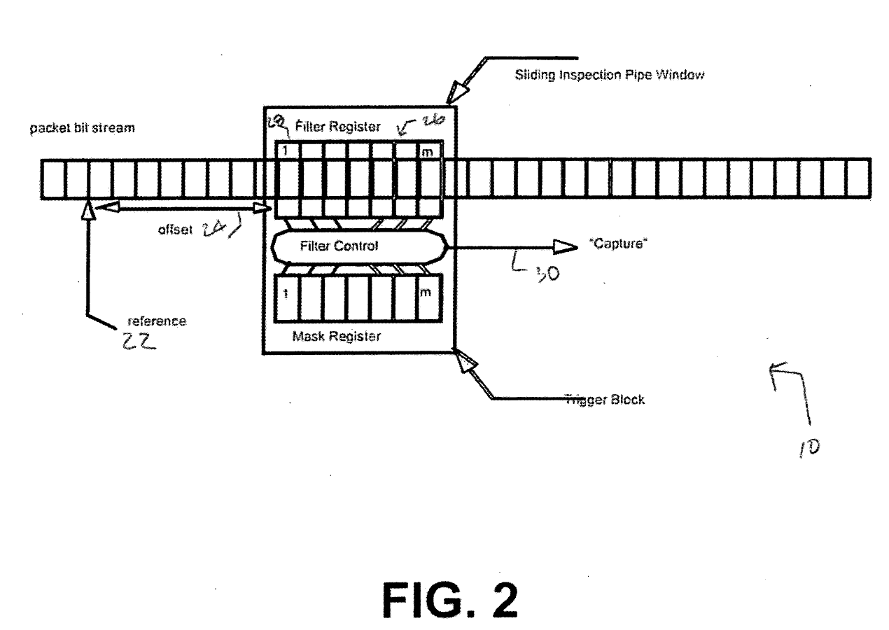

The inspection pipe's window (relative to start of the packets bit stream) is a function of; reference value 225 offset value 24 and mask value 26. Reference value 22 typically defines delineation points within a frame such as the start of L2 and L3 headers. The offset value defines the number of bytes from this reference value where the inspection pipe begins. The mask value defines which of the filter bit values are to be used in the comparison. Thus, based on user definable filter criteria input through software command and under the control of software, data at variable and user-definable locations within a traffic element can be evaluated. As shown in FIG. 2, register size defines the size (width) of the window, with the understanding that multiple windows may be cascaded together to extend the width of the window. The offset value points to the start of the filter register, which is also the same as the start of the inspection pipe window. The software interface that the user uses provide many ‘knobs’ for control that gives the user flexibility in placing the window.

As the data bit stream flows through this ‘pipe’ unimpeded, comparisons between the filter and mask values are made, if there is a match, the packet, or other type of traffic element, under inspection is copied through capture path 21, a bus, for example, into storage 18 as shown in FIG. 1, when capture apparatus 16 is instructed to open and allow the bits present, at its inputs to pass through for later analysis by the analysis and display utilities 20.

These and many other objects and advantages will be readily apparent to one skilled in the art from the foregoing specification when read in conjunction, with the appended drawings. It is to be understood that the embodiments herein illustrated are examples only, and that the scope of the invention is to be defined solely by the claims when accorded a full range of equivalents.

What is claimed is:

1. A method for evaluating traffic elements within a network device, comprising:
receiving the traffic elements trough an inspection pipe;
comparing each traffic element that passes through the inspection pipe to a set of user definable criteria values for a predetermined location within the traffic element;
determining whether a traffic element matches the set of user definable criteria values;
identifying each traffic element that matches the set of user definable criteria values for evaluation; and
storing each traffic element identified for evaluation to a storage device.

2. The method of claim 1 wherein the predetermined location of the traffic element is variable according to the user-definable criteria values.

3. The method of claim 2 wherein the user definable variable values include, offset reference, filter and mask values.

4. The method of claim 1 wherein a traffic element is a packet.

5. The method of claim 1 wherein each traffic element that is stored is stored in response to a control signal from a filter control.

6. A system for evaluating traffic elements within a network device, comprising:
art inspection pipe for receiving the traffic elements;
one or more trigger blocks for comparing each traffic element that passes through the inspection pipe to a set of user definable criteria values for a predetermined location within the traffic element;
one or more filter controls for determining whether a traffic element matches the set of filter criteria values; and
storing each traffic element identified for evaluation to a storage device based on a signal from one or more of the one or more filter controls.

7. The system of claim 6 wherein the predetermined location of the traffic element is defined by the user definable criteria values.

8. The system of claim 7 wherein the user definable criteria values include offset reference, filter and mask values.

9. The system of claim 6 wherein a traffic element is a packet.

10. The system of claim 6 wherein each traffic element that is stored is stored in response to a control signal from a filter control.

11. A system for evaluating traffic elements within a network device, comprising:
a CMTS, the CMTS including a FPGA device coupled to a processor and a memory, the FPGA defining:
an inspection pipe for receiving the traffic elements;
one or more trigger blocks for comparing each traffic element that passes through the inspection pipe to a set of user definable criteria values for a predetermined location within the traffic element;
one or more filter controls for determining whether a traffic element matches the set of filter criteria values; and
storing each traffic element identified for evaluation to a storage device based on a signal from one or more of the one or more filter controls.

12. The system of claim 11 wherein the predetermined location of the traffic element is defined by the user definable criteria values.

13. The system of claim 12 wherein the user definable criteria values include offset, reference, filter and mask values.

14. The system of claim 11 wherein a traffic element is a packet.

15. The system of claim 11 wherein each traffic element that is stored is stored in response to a control signal from a filter control.
